(19) United States
(12) Patent Application Publication
(10) Pub. No.: US 2004/0185635 A1
(43) Pub. Date: Sep. 23, 2004

(54) Semiconductor device and method for fabricating the same

(75) Inventor: Toshitaka Tatsunari, Kyoto (JP)

Correspondence Address: Jack Q. Lever, Jr., McDERMOTT, WILL & EMERY, 600 Thirteenth Street, N.W., Washington, DC, 20005-3096, US

(73) Assignee: MATSUSHITA ELECTRIC INDUSTRIAL CO., LTD.

(21) Appl. No.: 10/790,858

(22) Filed: Mar. 3, 2004

(30) Foreign Application Priority Data
Mar. 19, 2003 (JP) 2003-074731

(51) Int. Cl. H01L 21/8242

(52) U.S. Cl. 438/396

(57) ABSTRACT

A semiconductor-device fabrication method includes the steps of: forming a first hydrogen barrier film over a substrate with a protective insulating film interposed therebetween; forming a capacitive lower electrode on the first hydrogen barrier film; forming, on the first hydrogen barrier film, a first insulating film which covers the side of the capacitive lower electrode and from which the surface thereof is exposed; forming a capacitive insulating film of an insulating metal oxide covering the boundary between the capacitive lower electrode and the first insulating film; forming a capacitive upper electrode on the capacitive insulating film; forming, on the first insulating film, a second insulating film covering the capacitive insulating film and the capacitive upper electrode; forming a sloped portion in the second insulating film corresponding to an edge of the capacitive upper electrode; and forming a second hydrogen barrier film on the second insulating film having the sloped portion.

### BACKGROUND OF THE INVENTION

The present invention relates to semiconductor devices including ferroelectric capacitors using insulating metal oxide films as capacitive insulating films and to methods for fabricating the devices.

As digital technology progresses in recent years, electronic equipment has markedly advanced with an accelerated tendency of processing and storing a large capacity of data. Therefore, semiconductor memory devices constituting semiconductor devices used in the electronic equipment have been downsized rapidly. In addition, to achieve high integration of dynamic RAMs, research and development has been widely conducted on techniques using high-dielectric-constant materials (high-κ materials) for capacitive insulating films constituting the semiconductor memory devices in place of silicon oxides or silicon nitrides, which haven been conventionally used.

In addition, techniques using ferroelectric films exhibiting spontaneous polarization have been also researched and developed for the purpose of bringing nonvolatile RAMs capable of operating at low voltages and of writing and reading data at high speed into active use. In semiconductor memory devices using ferroelectric films as capacitive insulating films, it is necessary to prevent a trouble in which the ferroelectric films lose their function as the capacitive insulating films due to the deterioration or loss of the spontaneous polarization caused by a reduction reaction of hydrogen. In particular, since ferroelectric materials are layered oxides including oxygen atoms, the ferroelectric materials are easily reduced by heat treatment performed in an oxygen atmosphere in a process for fabricating a semiconductor device, resulting in the problem that the spontaneous polarization of the ferroelectric films deteriorates or are lost readily.

Examples of the heat treatment performed in an oxygen atmosphere in a fabrication process of a semiconductor device include hydrogen annealing which is performed at 400° C. for about 10 to 30 minutes, for example, to maintain the characteristics of a transistor after the formation of aluminum wiring.

Hereinafter, a conventional semiconductor device including a capacitive insulating film made of a ferroelectric film disclosed in Japanese Laid-Open Publication No. 4-102367 will be described with reference to FIG. 11.

As shown in FIG. 11, a buried isolation 11 is formed in the surface of a semiconductor substrate 10. Gate electrodes 13 are formed on a region of the semiconductor substrate 10 surrounded with the isolation 11, with a gate insulating film 12 interposed therebetween. Source/drain regions 14 and 15 are formed in part of the surface of the semiconductor substrate 10 surrounded with the isolation 11. Bit lines 16 are connected to the respective drain regions 15. The gate electrodes 13 and the source/drain regions 14 and 15 together form field-effect transistors serving as transistors for memory devices, and the gate electrodes 13 serve as word lines.

Over the semiconductor substrate 10, a protective insulating film 17 is formed to cover the gate electrodes 13, the source/drain regions 14 and 15 and the bit lines 16. Contact plugs 18 of tungsten are buried in the protective insulating film 17 to reach the respective source regions 14 through the protective insulating film 17. Capacitive lower electrodes 19 are formed on the protective insulating film 17, being connected to the tops of the contact plugs 18. The capacitive lower electrodes 19 is made of a conductive multilayer barrier film which is a multilayer film constituted by a Pt film, an IrO₂ film, an Ir film and a TiAlN film and prevents oxygen and hydrogen from passing therethrough.

A first hydrogen barrier film 20 of a silicon nitride film is formed between the capacitive lower electrodes 19 on the protective insulating film 17. Over the capacitive lower electrodes 19 and the first hydrogen barrier film 20, a capacitive insulating film 21 of a ferroelectric film and capacitive upper electrodes 22 are formed. The capacitive lower electrodes 19, the capacitive insulating film 21 and the capacitive upper electrodes 22 together form ferroelectric capacitors.

The conductive multilayer barrier film constituting the capacitive lower electrodes 19 includes the IrO₂ film and the Ir film in order to prevent tungsten constituting the contact plugs from reacting with oxygen abnormally in oxygen annealing performed at 850° C. for three minutes, for example, to crystallize the ferroelectric film to be the capacitive insulating film 21.

On the first hydrogen barrier film 20, a second hydrogen barrier film 23 made of Al₂O₃ (alumina) and TiAlO (titanium aluminum oxide) is formed by spattering to cover the capacitive insulating film 21 and the capacitive upper electrodes 22.

However, in the conventional semiconductor device, the oxygen annealing for crystallizing the ferroelectric film to be the capacitive insulating film 21 causes peeling inside the capacitive lower electrodes 19, thus arising a first problem of incapability of completely preventing the entry of hydrogen into the capacitive insulating film 21 in the heat treatment performed in a hydrogen atmosphere.

In addition, the insufficient crystallinity and coverage of the second hydrogen barrier film 23 leads to a second problem that the second hydrogen barrier film 23 cannot completely prevent the entry of hydrogen.

### SUMMARY OF THE INVENTION

It is therefore an object of the present invention to prevent peeling from occurring inside the capacitive lower electrodes during the oxygen annealing for crystallizing the ferroelectric film to be the capacitive insulating film. It is another object of the present invention is to ensure prevention of the entry of hydrogen into the capacitive insulating film in the annealing performed in a hydrogen atmosphere.

### First Finding

Hereinafter, it will be described how the first problem occurs, based on an investigation done by the present inventor.

As described above, to crystallize the ferroelectric film to be the capacitive insulating film 21, oxygen annealing is generally performed in the temperature range from 650° C. to 850° C. FIG. 12 shows a thermal stress hysteresis loop representing a relationship between a thermal stress applied onto the first oxygen barrier film 20 by the oxygen annealing and the temperature of the semiconductor substrate. The oxygen annealing in this case was performed at a temperature rise rate of +4° C./min. and a temperature drop rate of −10° C./min. The holding time at 850° C. was 30 minutes. The positive side of the ordinate refers to a tensile stress and the negative side thereof refers to a compressive stress.

As shown in FIG. 12, when the substrate temperature is 600° C. or higher, the stress on the first hydrogen barrier film 20 changes from the compressive direction to the tensile direction.

In view of this, the present inventor found that peeling occurs inside the capacitive lower electrodes 19 because of the change in the stress from the compressive direction to the tensile direction, combined with the fact that adherence at interfaces between the layers, especially between the Ir film and the TiAlN film, in the capacitive lower electrodes 19 is inherently poor. As described above, if peeling occurs inside the capacitive lower electrodes 19, the peeled surface acts as a path of hydrogen, so that it is difficult to completely prevent the entry of hydrogen into the capacitive insulating film 22.

A first solution according to the present invention is to prevent a change in the stress on the first hydrogen barrier film from reaching the capacitive lower electrodes even when the stress changes from the compressive direction to the tensile direction.

### Second Finding

Hereinafter, it will be described how the second problem occurs based on an investigation done by the present inventor.

The second hydrogen barrier film 23 generally includes an Al₂O₃ film and other films deposited by a spattering process in which no hydrogen is generated during the deposition.

Suppose that the Al₂O₃ film constituting the second hydrogen barrier film 23 is formed by a CVD process, the reaction of 2AlCl₃+3H₂+3CO₂→Al₂O₃+3CO+6HCl occurs. In such a case, the deposition gas contains hydrogen, so that the ferroelectric capacitor deteriorates only the deposition of the second hydrogen barrier film 23 with the CVD process.

In view of this, the second hydrogen barrier film 23 including the Al₂O₃ film and other films is generally formed using a sputtering process in which no hydrogen is generated during the deposition. However, films formed by sputtering exhibit poor step coverages in general.

The present inventor found the fact that the second hydrogen barrier film 23 formed by sputtering exhibits poor coverage in portions corresponding to the edges of the ferroelectric capacitor, and thus have its crystallinity and density, which greatly affect the barrier function against hydrogen, deteriorate so that a hydrogen path is created along the crystal grain boundary of the second hydrogen barrier film 23. As a result, the second hydrogen barrier film 23 cannot completely prevent the entry of hydrogen.

A second solution according to the present invention is to enhance the coverage in portions of the second hydrogen barrier film corresponding to the edges of the ferroelectric capacitor.

The present invention was made based on the first and second findings.

A first semiconductor device according to the present invention includes: a first hydrogen barrier film formed over a substrate; a capacitive lower electrode formed on the first hydrogen barrier film; a first insulating film formed on the first hydrogen barrier film to cover a side of the capacitive lower electrode and have the upper surface of the capacitive lower electrode exposed therefrom; a capacitive insulating film made of an insulating metal oxide and formed across the boundary between the capacitive lower electrode and the first insulating film; a capacitive upper electrode formed on the capacitive insulating film; a second insulating film formed on the first insulating film to cover the capacitive insulating film and the capacitive upper electrode and having a sloped portion at a position corresponding to an edge of the capacitive upper electrode; and a second hydrogen barrier film formed on the second insulating film.

With the first inventive semiconductor device, the capacitive lower electrode is provided on the first hydrogen barrier film, so that even if the stress on the first hydrogen barrier film changes from the compressive direction to the tensile direction, this stress change has no harmful effect on the capacitive lower electrode, so that no peeling occurs inside the capacitive lower electrode. Accordingly, no hydrogen path is created inside the capacitive lower electrode. In addition, the second hydrogen barrier film is formed on the second insulating film having a sloped portion corresponding to an edge of the capacitive upper electrode. This improves the coverage in the portion of the second hydrogen barrier film corresponding to an edge of the capacitive upper electrode, thus enhancing the crystallinity and density of the second hydrogen barrier film. Accordingly, no hydrogen path is created along the grain boundary in the second hydrogen barrier film, so that the second hydrogen barrier film prevents the entry of hydrogen as intended. As a result, the first inventive semiconductor device ensures the prevention of the entry of hydrogen into the capacitive insulating film.

A second semiconductor device according to the present invention includes: a first hydrogen barrier film formed over a substrate; a capacitive lower electrode formed on the first hydrogen barrier film; a first insulating film formed on the first hydrogen barrier film to cover a side of the capacitive lower electrode and have the upper surface of the capacitive lower electrode exposed therefrom; a capacitive insulating film made of an insulating metal oxide and formed across the boundary between the capacitive lower electrode and the first insulating film; a capacitive upper electrode formed on the capacitive insulating film; a second insulating film formed on the first insulating film to cover the capacitive insulating film and the capacitive upper electrode; a third insulating film made of a different material from that of the second insulating film, formed to cover the second insulating film, and rounded by reflowing in portion corresponding to an edge of the capacitive upper electrode; and a second hydrogen barrier film formed on the third insulating film.

With the second inventive semiconductor device, the capacitive lower electrode is provided on the first hydrogen barrier film, so that even if the stress on the first hydrogen barrier film changes from the compressive direction to the tensile direction, this stress change has no harmful effect on the capacitive lower electrode, so that no peeling occurs inside the capacitive lower electrode. Accordingly, no hydrogen path is created inside the capacitive lower electrode. In addition, the second hydrogen barrier film is formed on the third insulating film having a portion which has been rounded by reflowing and corresponds to an edge of the capacitive upper electrode. This improves the coverage in the portion of the second hydrogen barrier film corresponding to an edge of the capacitive upper electrode, thus enhancing the crystallinity and density of the second hydrogen barrier film. Accordingly, no hydrogen path is created along the grain boundary in the second hydrogen barrier film, so that the second hydrogen barrier film prevents the entry of hydrogen as intended. As a result, the second inventive semiconductor device ensures the prevention of the entry of hydrogen into the capacitive insulating film.

In the first or second inventive semiconductor device, it is preferable that a ferroelectric capacitor constituted by the capacitive lower electrode, the capacitive insulating film and the capacitive upper electrode is completely covered with the first and second hydrogen barrier films.

Then, the prevention of the entry of hydrogen into the capacitive insulating film is further ensured.

In the first or second inventive semiconductor device, the first and second insulating films are preferably formed into an island shape and the periphery of the first hydrogen barrier film is preferably connected to the bottom of the second hydrogen barrier film so that the ferroelectric capacitor is completely covered with the first and second hydrogen barrier films.

Then, the prevention of the entry of hydrogen into the capacitive insulating film is further ensured.

In the first or second inventive semiconductor device, the effects of the present invention is exhibited more advantageously especially when the capacitive lower electrode is made of a multilayer film in which a TiN film, a TiAlN film, an Ir film, an IrO₂ film and a Pt film are stacked in this order,

Specifically, if the capacitive lower electrode is made of the multilayer film described above, the adherence at the interface between the layers, especially between the Ir film and the TiAlN film, in the capacitive lower electrode is liable to deteriorate when the capacitive lower electrode is affected by a change of a stress. However, in the first or second inventive semiconductor device, the capacitive lower electrode is less affected by the change of the stress, so that the adherence at the interface between the layers in the capacitive lower electrode is less prone to decrease.

In the second inventive semiconductor device, the third insulating film is preferably formed with an ozone CVD process and made of an undoped silicon oxide film or a silicon oxide film doped with at least one of boron or phosphorus.

Then, the third insulating film is rounded by reflowing in a portion corresponding to an edge of the capacitive upper electrode as intended.

A first method for fabricating a semiconductor device according to the present invention includes the steps of: forming a first hydrogen barrier film over a substrate with a protective insulating film interposed therebetween; forming a capacitive lower electrode on the first hydrogen barrier film; forming a first insulating film on the first hydrogen barrier film so that the first insulating film covers a side of the capacitive lower electrode and the upper surface of the capacitive lower electrode is exposed; forming a capacitive insulating film of an insulating metal oxide so that the capacitive insulating film covers the boundary between the capacitive lower electrode and the first insulating film; forming a capacitive upper electrode on the capacitive insulating film; forming a second insulating film on the first insulating film so that the second insulating film covers the capacitive insulating film and the capacitive upper electrode; forming a sloped portion in the second insulating film at a position corresponding to an edge of the capacitive upper electrode; and forming a second hydrogen barrier film on the second insulating film having the sloped portion.

With the first inventive method, the capacitive lower electrode is provided on the first hydrogen barrier film, so that even if the stress on the first hydrogen barrier film changes from the compressive direction to the tensile direction, this stress change has no harmful effect on the capacitive lower electrode, so that no peeling occurs inside the capacitive lower electrode. Accordingly, no hydrogen path is created inside the capacitive lower electrode. In addition, the second hydrogen barrier film is formed on the second insulating film having a sloped portion corresponding to an edge of the capacitive upper electrode. This improves the coverage in the portion of the second hydrogen barrier film corresponding to an edge of the capacitive upper electrode, thus enhancing the crystallinity and density of the second hydrogen barrier film. Accordingly, no hydrogen path is created along the grain boundary in the second hydrogen barrier film, so that the second hydrogen barrier film prevents the entry of hydrogen as intended. As a result, the first inventive semiconductor device ensures the prevention of the entry of hydrogen into the capacitive insulating film.

In the first inventive method; the step of forming the sloped portion preferably includes the step of performing sputtering on the second insulating film with inert ions to form the sloped portion.

This sputtering on the second insulating film with inert ions ensures the formation of the sloped portion in the second insulating film corresponding to an edge of the capacitive upper electrode.

In the first inventive method, the step of forming the sloped portion preferably includes the step of etching the entire surface of the second insulating film to form the sloped portion.

This etching on the entire surface of the second insulating film ensures the formation of the sloped portion in the second insulating film corresponding to an edge of the capacitive upper electrode.

The first inventive method preferably further includes the step of selectively etching the second insulating film and the first insulating film to form the second insulating film and the first insulating film into an island shape, between the step of forming the sloped portion and the step of forming the second hydrogen barrier film, wherein the step of forming the second hydrogen barrier film includes the step of connecting the periphery of the first hydrogen barrier film and the bottom of the second hydrogen barrier film to each other so that a ferroelectric capacitor constituted by the capacitive lower electrode, the capacitive insulating film and the capacitive upper electrode is completely covered with the first and second hydrogen barrier films.

Then, the prevention of the entry of hydrogen into the capacitive insulating film is further ensured.

A second method for fabricating a semiconductor device according to the present invention includes the steps of: forming a first hydrogen barrier film over a substrate with a protective insulating film interposed therebetween; forming a capacitive lower electrode on the first hydrogen barrier film; forming a first insulating film on the first hydrogen barrier film so that the first insulating film covers a side of the capacitive lower electrode and the upper surface of the capacitive lower electrode is exposed; forming a capacitive insulating film of an insulating metal oxide so that the capacitive insulating film covers the boundary between the capacitive lower electrode and the first insulating film; forming a capacitive upper electrode on the capacitive insulating film; forming a second insulating film on the first insulating film so that the second insulating film covers the capacitive insulating film and the capacitive upper electrode; forming, on the second insulating film, a third insulating film made of a different material from that of the second insulating film; performing a reflowing process on the third insulating film so that a portion of the third insulating film corresponding to an edge of the capacitive upper electrode is rounded; and forming a second hydrogen barrier film on the third insulating film having the rounded portion corresponding to the edge of the capacitive upper electrode.

With the second inventive method, the capacitive lower electrode is provided on the first hydrogen barrier film, so that even if the stress on the first hydrogen barrier film changes from the compressive direction to the tensile direction, this stress change has no harmful effect on the capacitive lower electrode, so that no peeling occurs inside the capacitive lower electrode. Accordingly, no hydrogen path is created inside the capacitive lower electrode. In addition, the second hydrogen barrier film is formed on the third insulating film having a portion which has been rounded by reflowing and corresponds to an edge of the capacitive upper electrode. This improves the coverage in the portion of the second hydrogen barrier film corresponding to an edge of the capacitive upper electrode, thus enhancing the crystallinity and density of the second hydrogen barrier film. Accordingly, no hydrogen path is created along the grain boundary in the second hydrogen barrier film, so that the second hydrogen barrier film prevents the entry of hydrogen as intended. As a result, the second inventive semiconductor device ensures the prevention of the entry of hydrogen into the capacitive insulating film.

In the second inventive method, the step of forming the third insulating film preferably includes the step of performing an ozone CVD process to form the third insulating film made of an undoped silicon oxide film or a silicon oxide film doped with at least one of boron and phosphorus.

Then, the third insulating film is rounded by reflowing in a portion corresponding to an edge of the capacitive upper electrode as intended.

The second inventive method preferably further includes the step of selectively etching the third insulating film, the second insulating film and the first insulating film to form the third insulating film, the second insulating film and the first insulating film into an island shape, between the step of performing the reflowing process on the third insulating film and the step of forming the second hydrogen barrier film, wherein the step of forming the second hydrogen barrier film includes the step of connecting the periphery of the first hydrogen barrier film and the bottom of the second hydrogen barrier film to each other so that a ferroelectric capacitor constituted by the capacitive lower electrode, the capacitive insulating film and the capacitive upper electrode is completely covered with the first and second hydrogen barrier films.

Then, the prevention of the entry of hydrogen into the capacitive insulating film is further ensured.

In the first or second inventive method, the effects of the present invention is exhibited more advantageously especially when the capacitive lower electrode is made of a multilayer film in which a TiN, a TiAlN film, an Ir film, an IrO₂ film and a Pt film are stacked in this order.

Specifically, if the capacitive lower electrode is made of the multilayer film described above, the adherence at the interface between the layers, especially between the Ir film and the TiAlN film, in the capacitive lower electrode is liable to deteriorate when the capacitive lower electrode is affected by a change of a stress. However, in the semiconductor device obtained with the first or second inventive method, the capacitive lower electrode is less affected by the change of the stress, so that the adherence at the interface between the layers in the capacitive lower electrode is less prone to decrease.

### BRIEF DESCRIPTION OF THE DRAWINGS

FIG. 1 is a cross-sectional view showing a semiconductor device according to a first embodiment.

FIGS. 2A through 2C are cross-sectional views showing respective process steps of a first method for fabricating the semiconductor device of the first embodiment.

FIGS. 3A through 3C are cross-sectional views showing respective process steps of the first method for fabricating the semiconductor device of the first embodiment.

FIGS. 4A through 4C are cross-sectional views showing respective process steps of a second method for fabricating the semiconductor device of the first embodiment.

FIGS. 5A through 5C are cross-sectional views showing respective process steps of the second method for fabricating the semiconductor device of the first embodiment.

FIG. 6 is a cross-sectional view showing a semiconductor device according to a third embodiment.

FIGS. 7A through 7C are cross-sectional views showing respective process steps of a method for fabricating the semiconductor device of the third embodiment.

FIGS. 8A through 8C are cross-sectional views showing respective process steps of the method for fabricating the semiconductor device of the third embodiment.

FIG. 9 is a diagram showing a relationship between the thickness of a TiN film to be a conductive film and the contact resistance between capacitive lower electrodes and contact plugs in the semiconductor device of the first embodiment.

FIG. 10 is a graph showing polarizations in ferroelectric films of a conventional semiconductor device and the semiconductor device of the first embodiment and a ferroelectric alone.

FIG. 11 is a cross-sectional view showing a conventional semiconductor device.

FIG. 12 is a graph showing a thermal stress hysteresis loop representing a relationship between a thermal stress on a first oxygen barrier film caused by oxygen annealing and the temperature of a semiconductor substrate.

### DESCRIPTION OF THE PREFERRED EMBODIMENTS

### Embodiment 1

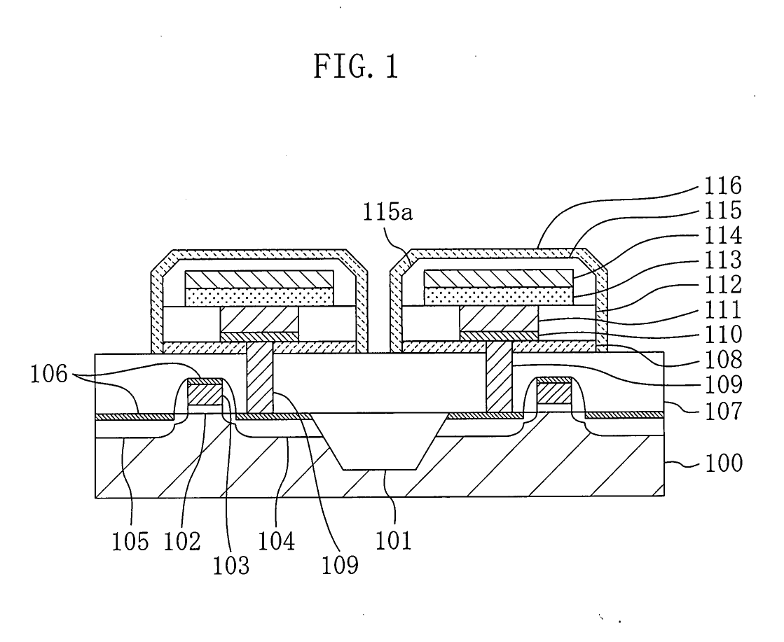

Hereinafter, a semiconductor device according to a first embodiment of the present invention will be described with reference to FIG. 1.

FIG. 1 shows a cross-sectional structure of the semiconductor device of the first embodiment. As shown in FIG. 1, a buried isolation 101 is formed in the surface of a semiconductor substrate 100 of silicon. Gate electrodes 103 are formed on a region of the semiconductor substrate 100 surrounded with the isolation 101, with a gate insulating film 102 interposed therebetween. Source/drain regions 104 and 105 are formed in part of the surface of the semiconductor substrate 100 surrounded with the isolation 101. A cobalt silicide layer 106 is formed in the surfaces of the gate electrodes 103 and the source/drain regions 104 and 105. The gate electrodes 103 and the source/drain regions 104 and 105 together form field-effect transistors serving as transistors for memory devices, and the gate electrodes 103 serve as word lines.

Over the semiconductor substrate 100, a protective insulating film 107 is formed to cover the gate electrodes 103 and the source/drain regions 104 and 105. A first hydrogen barrier film 108 is formed on a predetermined region of the protective insulating film 107. Contact plugs 109 of tungsten are buried in the first hydrogen barrier film 108 and the protective insulating film 107 to penetrate therethrough. The bottoms of the contact plugs 109 are connected to the respective source regions 104.

A conductive film 110 is formed on the first hydrogen barrier film 108 and connected to the tops of the contact plugs 109. Capacitive lower electrodes 111 are formed on the conductive film 110. The conductive film 110 and the capacitive lower electrodes 111 are surrounded with a first insulating film 112 whose upper surface is flush with the upper surfaces of the capacitive lower electrodes 111.

On the capacitive lower electrodes 111 and the first insulating film 112, a capacitive insulating film 113 made of a ferroelectric film is formed. Capacitive upper electrodes 114 are formed on the capacitive insulating film 113. The capacitive lower electrodes 111, the capacitive insulating film 113 and the capacitive upper electrodes 114 together form ferroelectric capacitors.

On the first insulating film 112, a second insulating film 115 is formed to cover the ferroelectric capacitors. The second insulating film 115 has sloped portions 115a corresponding to the edges of the ferroelectric capacitors.

A second hydrogen barrier film 116 is formed to cover the first hydrogen barrier film 108, the first insulating film 112 and the second insulating film 115. The bottom of the second hydrogen barrier film 116 is connected to the periphery of the first hydrogen barrier film 108.

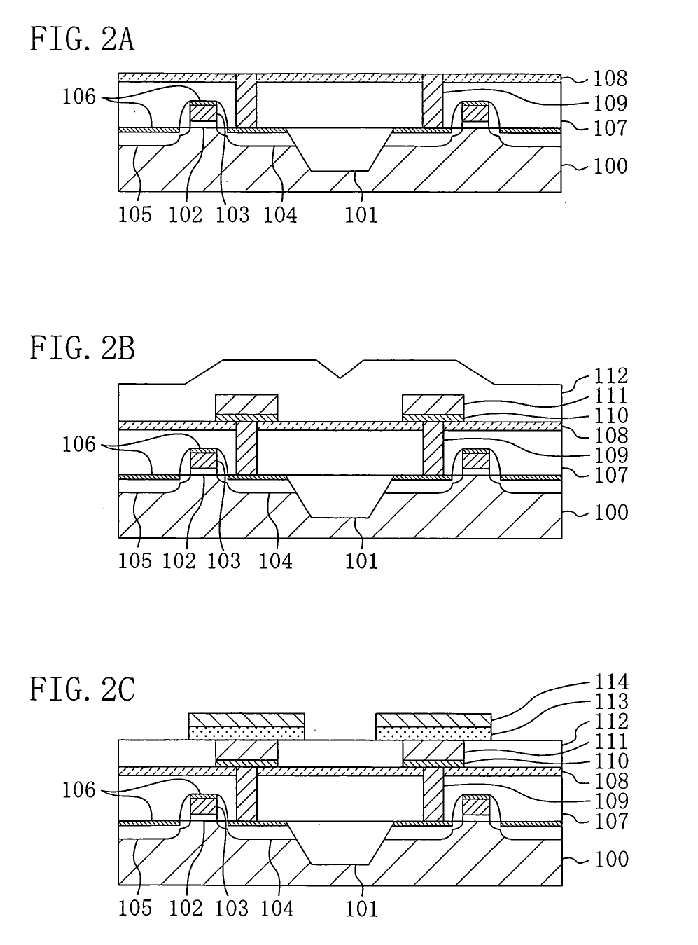

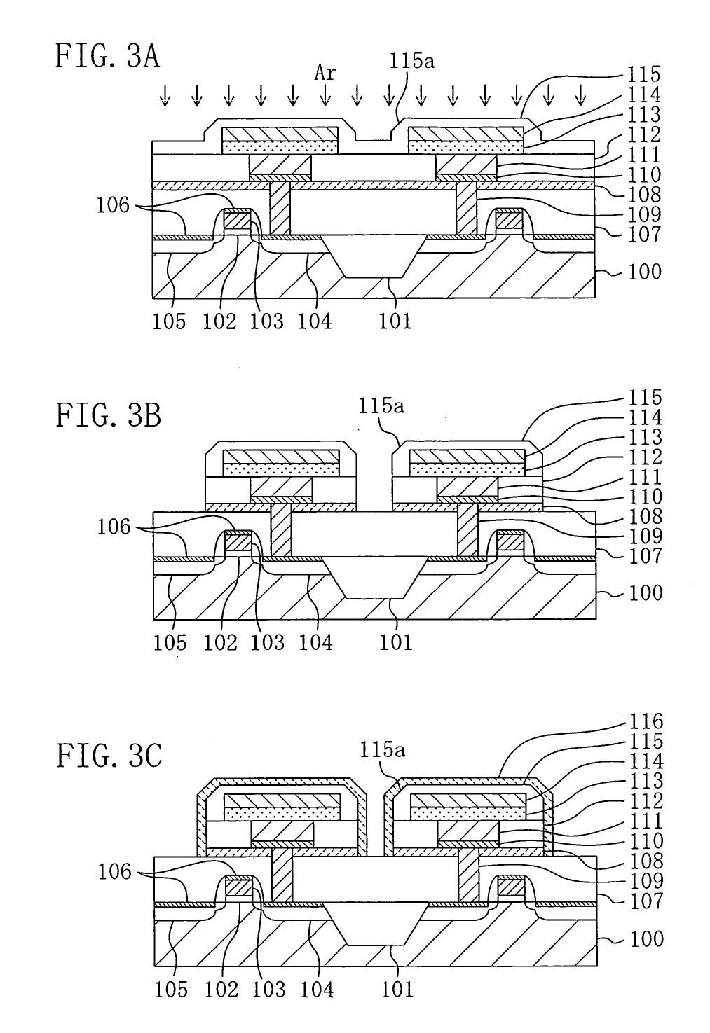

Hereinafter, a first method for fabricating the semiconductor device of the first embodiment will be described with reference to FIGS. 2A through 2C and FIGS. 3A through 3C.

First, as shown in FIG. 2A, a buried isolation 101 with a thickness of 300 nm to 750 nm is formed in the surface of a semiconductor substrate 100 of silicon, and then a gate insulating film 102 with a thickness of 3 nm to 12 nm is formed on a region of the semiconductor substrate 100 surrounded with the isolation 101. Thereafter, an undoped amorphous silicon film is deposited to a thickness of 70 nm to 200 nm on the gate insulating film 102, and then patterned by dry etching, thereby forming gate electrodes 103.

Subsequently, boron ions are implanted into part of the surface of the semiconductor substrate 100 surrounded with the isolation 101 at a dose of 5 to 10×10¹⁵/cm² using the gate electrodes 103 as a mask, and then activation annealing is performed at temperatures ranging from 650° C. to 850° C. for 10 to 30 minutes, thereby forming source/drain regions 104 and 105. A cobalt silicide layer 106 with a thickness of 5 nm to 20 nm is formed in the surfaces of the gate electrodes 103 and the source/drain regions 104 and 105.

Then, a protective insulating film 107 of a BPSG film with a thickness of 300 nm to 700 nm is formed over the semiconductor substrate 100 to cover the gate electrodes 103 and the source/drain regions 104 and 105. The BPSG film has a boron concentration of 0.5 wt % to 2.5 wt % and a phosphorus concentration of 1.0 wt % to 6.0 wt %. Subsequently, a first hydrogen barrier film 108 of a SiN (silicon nitride) film is deposited by a CVD process to a thickness of 50 nm to 200 nm.

Thereafter, contact holes are formed in the first hydrogen barrier film 108 and the protective insulating film 107, and then a tungsten film is deposited by a CVD process over the entire surface of the first hydrogen barrier film 108. Then, the tungsten film is etched back or subjected to CMP, thereby forming contact plugs 109 penetrating through the first hydrogen barrier film 108 and the protective insulating film 107.

Next, as shown in FIG. 2B, a TiN film is deposited by a CVD process to a thickness of 5 nm to 50 nm on the first hydrogen barrier film 108, and then a multilayer film in which a TiAlN film with a thickness of 10 nm to 100 nm, an Ir film with a thickness of 50 nm to 150 nm, an IrO₂ film with a thickness of 50 nm to 150 nm and a Pt film with a thickness of 50 nm to 150 nm are stacked in this order is formed by a sputtering process on the TiN film. Thereafter, the multilayer film and the TiN film are patterned, thereby forming capacitive lower electrodes 111 and a conductive film 110 out of the multilayer film and the TiN film, respectively.

Subsequently, a first insulating film 112 with a thickness of 155 nm to 800 nm is deposited by an HDP (high density plasma)-CVD process on the first hydrogen barrier film 108 to cover the conductive film 110 and the capacitive lower electrodes 111.

Then, as shown in FIG. 2C, the first insulating film 112 is polished by a CMP process until the capacitive lower electrodes 111 are exposed so that the upper surface of the first insulating film 112 is flush with the upper surfaces of the capacitive lower electrodes 111.

Thereafter, a ferroelectric film having a bismuth layered perovskite structure and made of a SrBi₂(Ta₁₋ₓNbₓ)₂O₉ film with a thickness of 50 nm to 150 nm is formed by an MOD (metal organic decomposition) process, an MOCVD (metal organic chemical vapor deposition) process, a sputtering process or a coating process on the capacitive lower electrodes 111 and the first insulating film 112. Then, a platinum film is deposited by a sputtering process to a thickness of 50 nm to 100 nm on the ferroelectric film. Thereafter, the platinum film and the ferroelectric film are patterned, thereby forming capacitive upper electrodes 114 and a capacitive insulating film 113 out of the platinum film and the ferroelectric film, respectively. In this manner, capacitors constituted by the capacitive lower electrodes 111, the capacitive insulating film 113 and the capacitive upper electrodes 114 are formed.

Then, as shown in FIG. 3A, a second insulating film 115 of a silicon oxide film with a thickness of 50 nm to 300 nm is formed over the first insulating film 112 to cover the capacitive insulating film 113 and the capacitive upper electrodes 114, and then sputtering is performed on the second insulating film 115 using argon ions in an argon plasma atmosphere, thereby forming sloped portions 115a in the second insulating film 115 corresponding to the edges of the capacitive upper electrodes 114. The argon sputtering is performed for 120 seconds under conditions of source power: 350 W, bias power: 250 W, and flow rate of argon gas: 5 mL/min. (under standard conditions), for example. In this case, the sputtering for forming the sloped portions 115a in the second insulating film 115 is performed such that the edges of the capacitive upper electrodes 114 are not exposed from the sloped portions 115a of the second insulating film 115.

Then, as shown in FIG. 3B, selective dry etching is performed on the second insulating film 115, the first insulating film 112 and the first hydrogen barrier film 108, thereby forming the second insulating film 115, the first insulating film 112 and the first hydrogen barrier film 108 into an island shape. In this case, the selective dry etching is performed such that the edges of the capacitive upper electrodes 114 are not exposed from the sloped portions 115a of the second insulating film 115.

Thereafter, oxygen annealing is performed using RTA (rapid thermal annealing) at 650° C. to 850° C. in an oxygen atmosphere for 15 seconds to 5 minutes, thereby crystallizing the ferroelectric film constituting the capacitive insulating film 113.

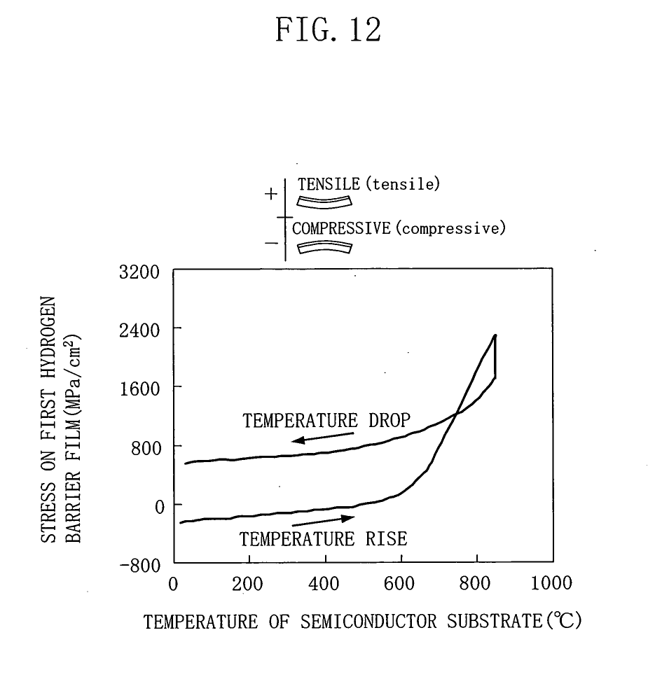

As has been described with reference to FIG. 12, the stress on the first hydrogen barrier film 108 changes through this oxygen annealing. However, this change of the stress on the first hydrogen barrier film 108 is suppressed by the conductive film 110 and the first insulating film 112. Accordingly, no peeling occurs at the interface between layers, especially between the Ir film and the TiAlN film, in the capacitive lower electrodes 111.

Subsequently, as shown in FIG. 3C, a second hydrogen barrier film 116 of an Al₂O₃ film or a TiAlO film is deposited by sputtering to a thickness of 5 nm to 100 nm to completely cover the second insulating film 115, the first insulating film 112 and the first hydrogen barrier film 108 which have been etched into an island shape. Then, the second hydrogen barrier film 116 is patterned and removed in part except for a portion surrounding the island-shaped second insulating film 115, first insulating film 112 and first hydrogen barrier film 108. In this case, the connection between the bottom of the second hydrogen barrier film 116 and the periphery of the first hydrogen barrier film 108 is also maintained.

According to the first embodiment, the second hydrogen barrier film 116 is deposited over the second insulating film 115 having the sloped portions 115a corresponding to the edges of the ferroelectric capacitors. Accordingly, though the second hydrogen barrier film 116 is deposited by sputtering, the coverage in the portions of the second hydrogen barrier film 116 corresponding to the edges of the ferroelectric capacitors is enhanced. This improves the crystallinity and density of the second hydrogen barrier film 116 in every part so that the occurrence of a hydrogen path is prevented. As a result, the barrier function against hydrogen improves.

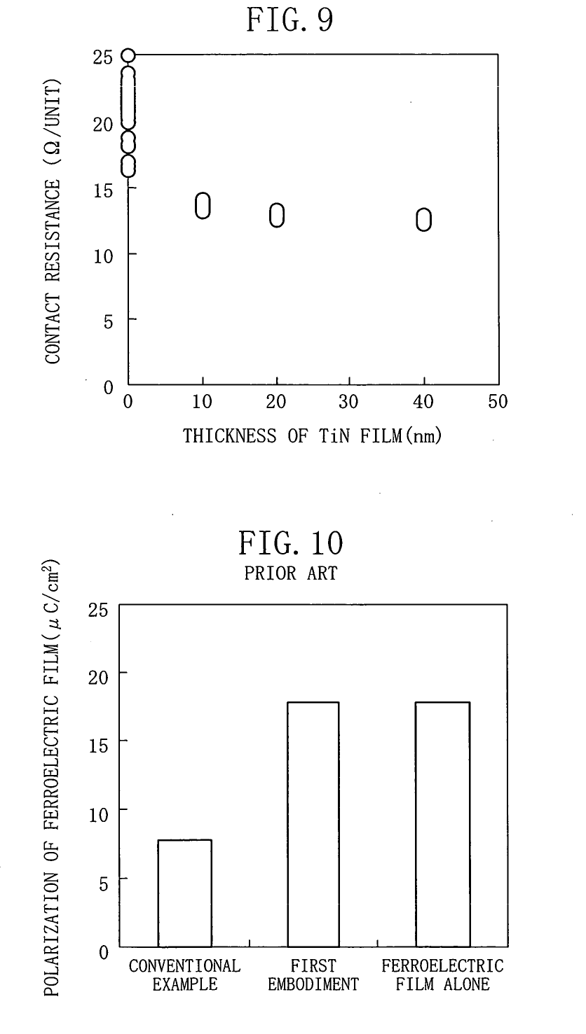

Hereinafter, results of tests conducted to evaluate the device of the first embodiment will be described. FIG. 9 shows a relationship between the thickness of the TiN film to be the conductive film 110 and the contact resistance between the capacitive lower electrodes 111 and the contact plugs 109. As is clear from FIG. 9, when the thickness of the TiN film is zero, i.e., the conductive film 110 is not provided, variation of the contact resistance is observed. On the other hand, when the thickness of the TiN film is 10 nm, 20 nm or 40 nm, the contact resistance is stable at small values. These facts show that peeling occurs at the interface between layers in the capacitive lower electrodes 111 so that the contact resistance varies in the absence of the conductive film 110 whereas no peeling occurs at the interface between layers in the capacitive lower electrodes 111 so that the contact resistance is stable at small values in the presence of the conductive film 110.

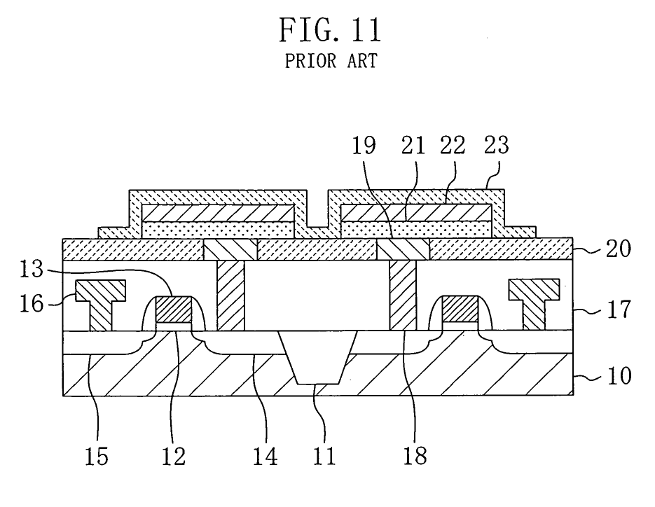

FIG. 10 shows the values of polarizations in ferroelectric films of the conventional semiconductor device shown in FIG. 11 and the semiconductor device of the first embodiment and in a ferroelectric film which is used alone (reference). As shown in FIG. 10, according to the first embodiment, it is possible to prevent the ferroelectric film constituting the capacitive insulating film 113 from being reduced and from deteriorating by hydrogen generated in a fabrication process. Accordingly, deterioration in the polarization of the ferroelectric film is reduced. In the first embodiment, the polarization value of the ferroelectric film constituting the capacitive insulating film 113 is almost equal to the polarization value of the ferroelectric film used alone (reference).

### Embodiment 2

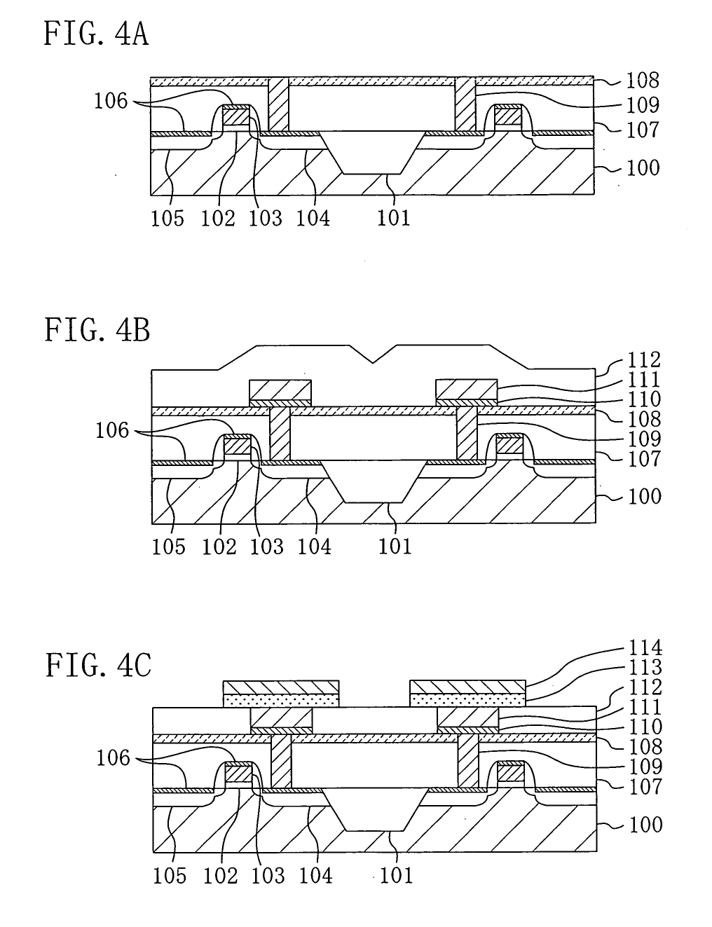

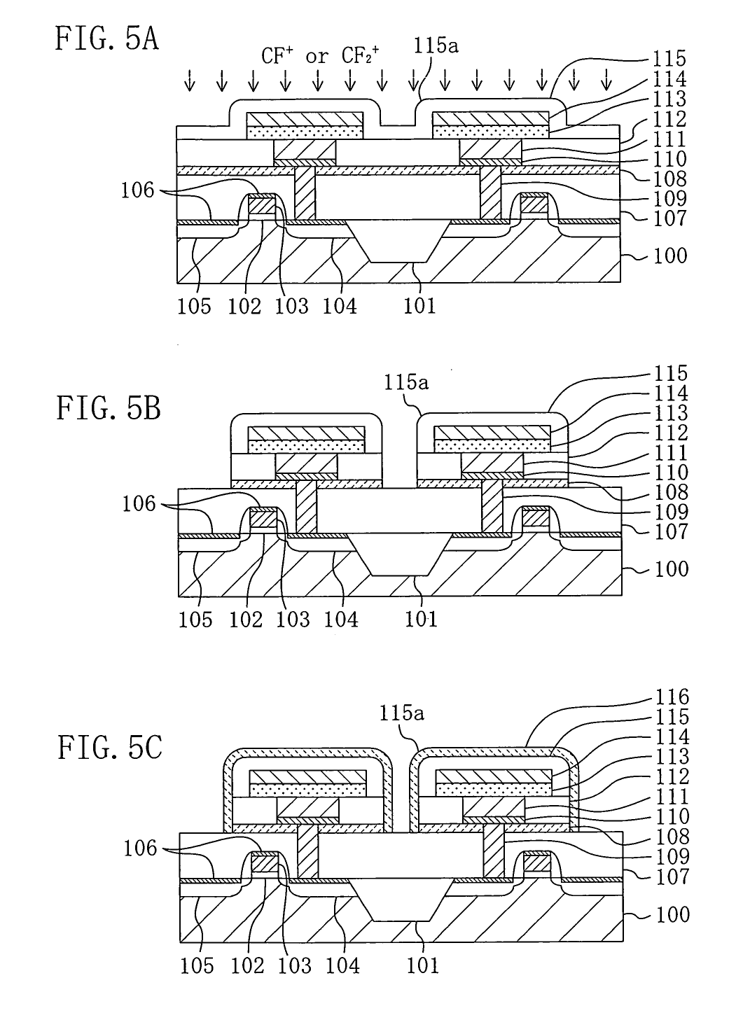

Hereinafter, as a second embodiment of the present invention, a second method for fabricating the semiconductor device of the first embodiment will be described with reference to FIGS. 4A through 4C and FIGS. 5A through 5C. The semiconductor device fabricated by the second method is different from the semiconductor device fabricated by the first embodiment, i.e., the first method, only in that the sloped portions 115a formed in the second insulating film 115 at positions corresponding to the edges of the ferroelectric capacitors are rounded.

First, as in the first embodiment, as shown in FIG. 4A, a buried isolation 101 with a thickness of 300 nm to 750 nm is formed in the surface of a semiconductor substrate 100 of silicon, and then a gate insulating film 102 with a thickness of 3 nm to 12 nm is formed on a region of the semiconductor substrate 100 surrounded with the isolation 101. Thereafter, an undoped amorphous silicon film is deposited to a thickness of 70 nm to 200 nm on the gate insulating film 102, and then patterned by dry etching, thereby forming gate electrodes 103. Subsequently, boron ions are implanted into part of the surface of the semiconductor substrate 100 surrounded with the isolation 101 using the gate electrodes 103 as a mask, and then activation annealing is performed, thereby forming source/drain regions 104 and 105. A cobalt silicide layer 106 with a thickness of 5 nm to 20 nm is formed in the surfaces of the gate electrodes 103 and the source/drain regions 104 and 105.

Then, a protective insulating film 107 of a BPSG film with a thickness of 300 nm to 700 nm is formed over the semiconductor substrate 100 to cover the gate electrodes 103 and the source/drain regions 104 and 105. Subsequently, a first hydrogen barrier film 108 of a SiN (silicon nitride) film is deposited by a CVD process to a thickness of 50 nm to 200 nm on the protective insulating film 107. Thereafter, contact holes are formed in the first hydrogen barrier film 108 and the protective insulating film 107, and then a tungsten film is deposited by a CVD process over the entire surface of the first hydrogen barrier film 108. Then, the tungsten film is etched back or subjected to CMP, thereby forming contact plugs 109 penetrating through the first hydrogen barrier film 108 and the protective insulating film 107.

Next, as shown in FIG. 4B, a TiN film is deposited by a CVD process to a thickness of 5 nm to 50 nm on the first hydrogen barrier film 108, and then a multilayer film in which a TiAlN film with a thickness of 10 nm to 100 nm, an Ir film with a thickness of 50 nm to 150 nm, an IrO₂ film with a thickness of 50 nm to 150 nm and a Pt film with a thickness of 50 nm to 150 nm are stacked in this order is formed by a sputtering process on the TiN film. Thereafter, the multilayer film and the TiN film are patterned, thereby forming capacitive lower electrodes 111 and a conductive film 110 out of the multilayer film and the TiN film, respectively.

Subsequently, a first insulating film 112 is deposited by an HDP-CVD process to a thickness of 155 nm to 800 nm on the first hydrogen barrier film 108 to cover the conductive film 110 and the capacitive lower electrodes 111.

Then, as shown in FIG. 4C, the first insulating film 112 is polished by a CMP process until the capacitive lower electrodes 111 are exposed so that the upper surface of the first insulating film 112 is flush with the upper surfaces of the capacitive lower electrodes 111.

Thereafter, a ferroelectric film having a bismuth layered perovskite structure and made of a SrBi₂(Ta₁₋ₓNbₓ)₂O₉ film with a thickness of 50 nm to 150 nm is formed by an MOD (metal organic decomposition) process, an MOCVD (metal organic chemical vapor deposition) process, a sputtering process or a coating process on the capacitive lower electrodes 111 and the first insulating film 112. Then, a platinum film is deposited by a sputtering process to a thickness of 50 nm to 100 nm on the ferroelectric film. Thereafter, the platinum film and the ferroelectric film are patterned, thereby forming capacitive upper electrodes 114 and a capacitive insulating film 113 out of the platinum film and the ferroelectric film, respectively. In this manner, capacitors constituted by the capacitive lower electrodes 111, the capacitive insulating film 113 and the capacitive upper electrodes 114 are formed.

Then, as shown in FIG. 5A, a second insulating film 115 of a silicon oxide film with a thickness of 50 nm to 300 nm is formed over the first insulating film 112 to cover the capacitive insulating film 113 and the capacitive upper electrodes 114, and then the entire surface of the second insulating film 115 is etched with oxide-film etching apparatus, for example, thereby forming rounded sloped portions 115a in the second insulating film 115 corresponding to the edges of the capacitive upper electrodes 114. The entire-surface etching is performed for 10 seconds under conditions of source power: 2200 W, bias power: 1300 W, pressure in the chamber 0.665 Pa, flow rate of C₂F₆ gas: 40 mL/min. (under standard conditions), and flow rate of O₂ gas: 2 mL/min. (under standard conditions), for example. In this case, the entire-surface etching for forming the rounded sloped portions 115a in the second insulating film 115 is performed such that the edges of the capacitive upper electrodes 114 and the capacitive insulating film 113 are not exposed from the rounded sloped portions 115a of the second insulating film 115.

Then, as shown in FIG. 5B, selective dry etching is performed on the second insulating film 115, the first insulating film 112 and the first hydrogen barrier film 108, thereby forming the second insulating film 115, the first insulating film 112 and the first hydrogen barrier film 108 into an island shape. In this case, the selective dry etching is performed such that the edges of the capacitive upper electrodes 114 and the capacitive insulating film 113 are not exposed from the rounded sloped portions 115a of the second insulating film 115.

Thereafter, oxygen annealing is performed using RTA at 650° C. to 850° C. in an oxygen atmosphere for 15 seconds to 5 minutes, thereby crystallizing the ferroelectric film constituting the capacitive insulating film 113.

As has been described with reference to FIG. 12, the stress on the first hydrogen barrier film 108 changes through this oxygen annealing. However, this change of the stress on the first hydrogen barrier film 108 is suppressed by the conductive film 110 and the first insulating film 112. Accordingly, no peeling occurs at the interface between layers, especially between the Ir film and the TiAlN film, in the capacitive lower electrodes 111.

Subsequently, as shown in FIG. 5C, a second hydrogen barrier film 116 of an Al₂O₃ film or a TiAlO film is deposited by sputtering to a thickness of 5 nm to 100 nm to completely cover the second insulating film 115, the first insulating film 112 and the first hydrogen barrier film 108 which have been etched into an island shape. Then, the second hydrogen barrier film 116 is patterned and removed in part except for a portion surrounding the island-shaped second insulating film 115, first insulating film 112 and first hydrogen barrier film 108. In this case, the connection between the bottom of the second hydrogen barrier film 116 and the periphery of the first hydrogen barrier film 108 is also maintained.

According to the second embodiment, the second hydrogen barrier film 116 is deposited over the second insulating film 115 having the rounded sloped portions 115a corresponding to the edges of the ferroelectric capacitors. Accordingly, though the second hydrogen barrier film 116 is deposited by sputtering, the coverage in the portions of the second hydrogen barrier film 116 corresponding to the edges of the ferroelectric capacitors is enhanced. This improves the crystallinity and density of the second hydrogen barrier film 116 in every part so that the occurrence of a hydrogen path is prevented. As a result, the barrier function against hydrogen improves.

### Embodiment 3

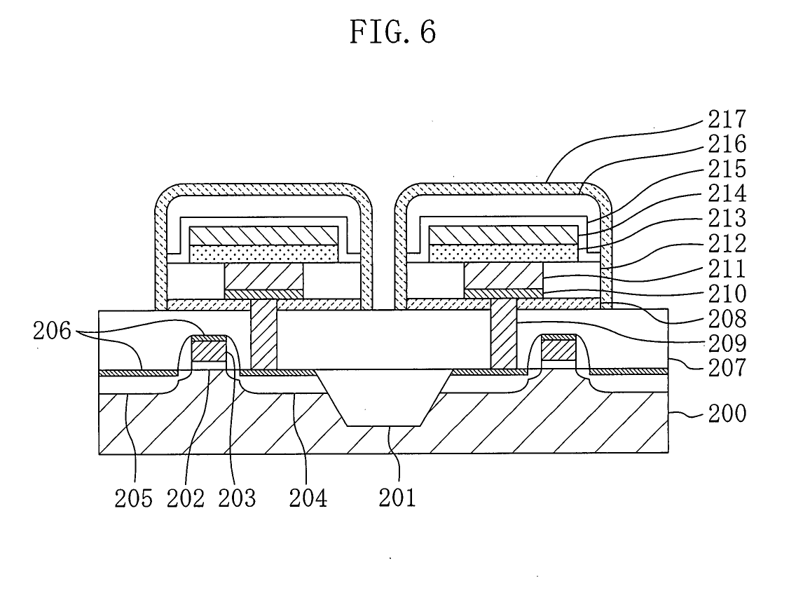

Hereinafter, a semiconductor device according to a third embodiment of the present invention will be described with reference to FIG. 6.

FIG. 6 shows a cross-sectional structure of the semiconductor device of the third embodiment. As shown in FIG. 6, a buried isolation 201 is formed in the surface of a semiconductor substrate 200 of silicon. Gate electrodes 203 are formed on a region of the semiconductor substrate 200 surrounded with the isolation 201, with a gate insulating film 202 interposed therebetween. Source/drain regions 204 and 205 are formed in part of the surface of the semiconductor substrate 200 surrounded with the isolation 201. A cobalt silicide layer 206 is formed in the surfaces of the gate electrodes 203 and the source/drain regions 204 and 205. The gate electrodes 203 and the source/drain regions 204 and 205 together form field-effect transistors serving as transistors for memory devices, and the gate electrodes 203 serve as word lines.

Over the semiconductor substrate 200, a protective insulating film 207 is formed to cover the gate electrodes 203 and the source/drain regions 204 and 205. A first hydrogen barrier film 208 is formed on a predetermined region of the protective insulating film 207. Contact plugs 209 of tungsten are buried in the first hydrogen barrier film 208 and the protective insulating film 207 to penetrate therethrough. The bottoms of the contact plugs 209 are connected to the respective source regions 204.

A conductive film 210 is formed on the first hydrogen barrier film 208 and connected to the tops of the contact plugs 209. Capacitive lower electrodes 211 are formed on the conductive film 210. The conductive film 210 and the capacitive lower electrodes 211 are surrounded with a first insulating film 212 whose upper surface is flush with the upper surfaces of the capacitive lower electrodes 211.

A capacitive insulating film 213 of a ferroelectric film is formed on the capacitive lower electrodes 211 and the first insulating film 212. Capacitive upper electrodes 214 are formed on the capacitive insulating film 213. The capacitive lower electrodes 211, the capacitive insulating film 213 and the capacitive upper electrodes 214 together form ferroelectric capacitors.

Over the first insulating film 212, a second insulating film 215 of an undoped silicon oxide film and a third insulating film 216 of a BPSG film are formed to cover the ferroelectric capacitors. As the third insulating film 216, an undoped silicon oxide film or a silicon oxide film doped with boron or phosphorus may be used instead of the BPSG film.

A second hydrogen barrier film 217 is formed to cover the first hydrogen barrier film 208, the first insulating film 212, the second insulating film 215 and the third insulating film 216. The bottom of the second hydrogen barrier film 217 is connected to the periphery of the first hydrogen barrier film 208.

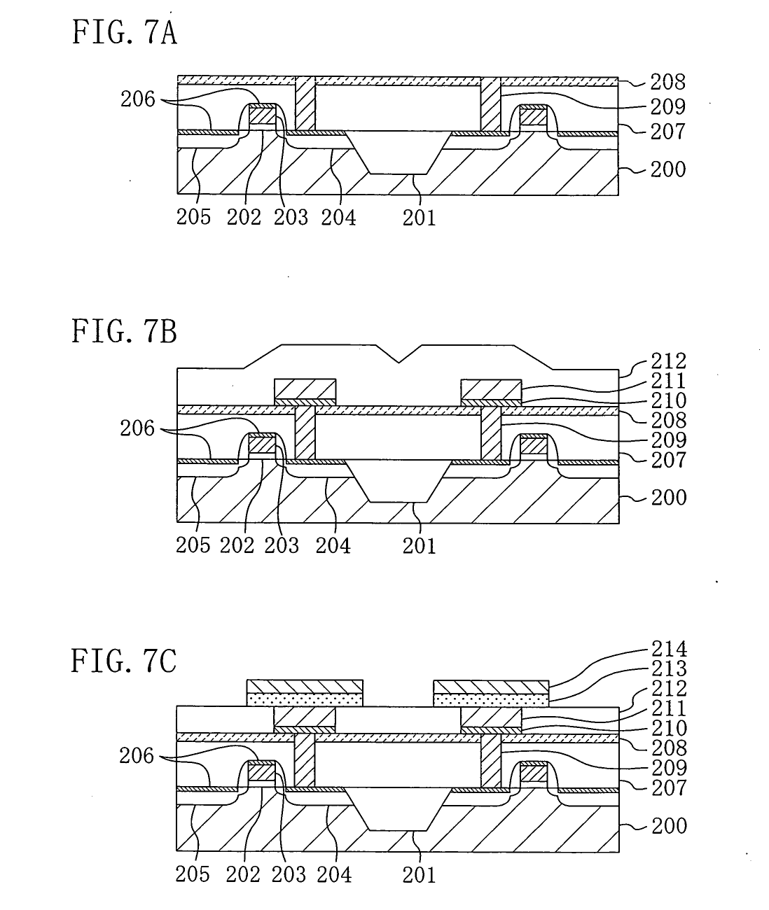

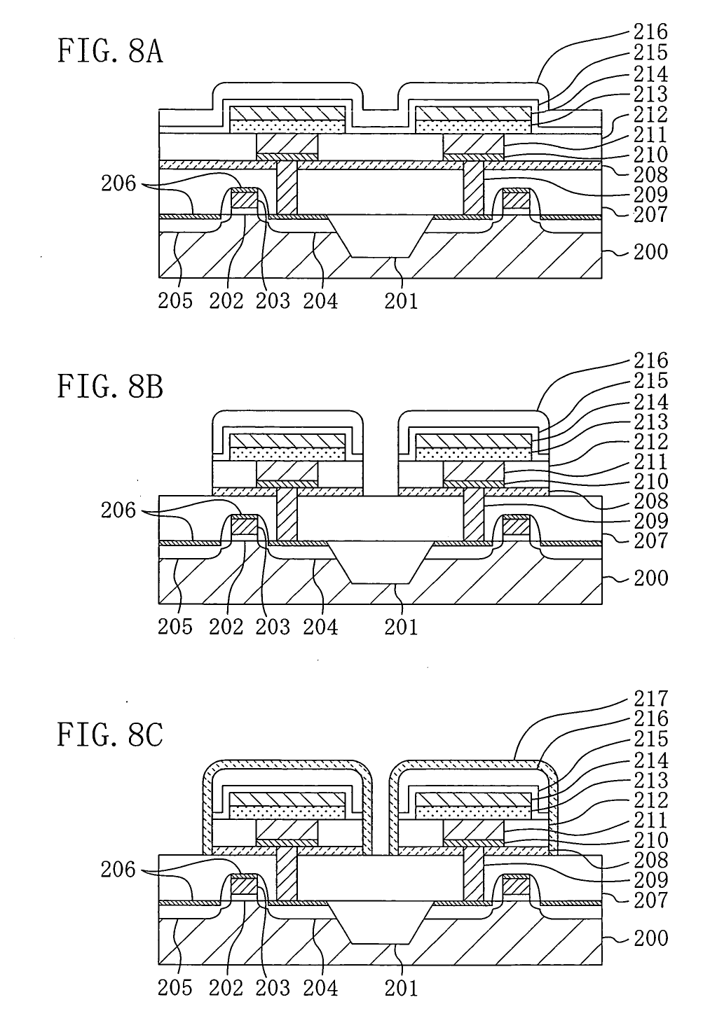

Hereinafter, a first method for fabricating the semiconductor device of the third embodiment will be described with reference to FIGS. 7A through 7C and FIGS. 8A through 8C.

First, as shown in FIG. 7A, a buried isolation 201 with a thickness of 300 nm to 750 nm is formed in the surface of a semiconductor substrate 200 of silicon, and then a gate insulating film 202 with a thickness of 3 nm to 12 nm is formed on a region of the semiconductor substrate 200 surrounded with the isolation 201. Thereafter, an undoped amorphous silicon film is deposited to a thickness of 70 nm to 200 nm on the gate insulating film 202, and then patterned by dry etching, thereby forming gate electrodes 203.

Subsequently, boron ions are implanted into part of the surface of the semiconductor substrate 200 surrounded with the isolation 201 at a dose of 5 to 10×10¹⁵/cm² using the gate electrodes 203 as a mask, and then activation annealing is performed at temperatures ranging from 650° C. to 850° C. for 10 to 30 minutes, thereby forming source/drain regions 204 and 205. A cobalt silicide layer 206 with a thickness of 5 nm to 20 nm is formed in the surfaces of the gate electrodes 203 and the source/drain regions 204 and 205.

Then, a protective insulating film 207 of a BPSG film with a thickness of 300 nm to 700 nm is formed over the semiconductor substrate 200 to cover the gate electrodes 203 and the source/drain regions 204 and 205. The BPSG film has a boron concentration of 0.5 wt % to 2.5 wt % and a phosphorus concentration of 1.0 wt % to 6.0 wt %. Subsequently, a first hydrogen barrier film 208 of a SiN (silicon nitride) film is deposited by a CVD process to a thickness of 50 nm to 200 nm.

Thereafter, contact holes are formed in the first hydrogen barrier film 208 and the protective insulating film 207, and then a tungsten film is deposited by a CVD process over the entire surface of the first hydrogen barrier film 208. Then, the tungsten film is etched back or subjected to CMP, thereby forming contact plugs 209 penetrating through the first hydrogen barrier film 208 and the protective insulating film 207.

Next, as shown in FIG. 7B, a TiN film is deposited by a CVD process to a thickness of 5 nm to 50 nm on the first hydrogen barrier film 208, and then a multilayer film in which a TiAlN film with a thickness of 10 nm to 100 nm, an Ir film with a thickness of 50 nm to 150 nm, an IrO₂ film with a thickness of 50 nm to 150 nm and a Pt film with a thickness of 50 nm to 150 nm are stacked in this order is formed by a sputtering process on the TiN film. Thereafter, the multilayer film and the TiN film are patterned, thereby forming capacitive lower electrodes 211 and a conductive film 210 out of the multilayer film and the TiN film, respectively.

Subsequently, a first insulating film 212 with a thickness of 155 nm to 800 nm is deposited by an HDP-CVD process on the first hydrogen barrier film 208 to cover the conductive film 210 and the capacitive lower electrodes 211.

Then, as shown in FIG. 7C, the first insulating film 212 is polished by a CMP process until the capacitive lower electrodes 211 are exposed so that the upper surface of the first insulating film 212 is flush with the upper surfaces of the capacitive lower electrodes 211.

Thereafter, a ferroelectric film having a bismuth layered perovskite structure and made of a SrBi₂(Ta₁₋ₓNbₓ)₂O₉ film with a thickness of 50 nm to 150 nm is formed by an MOD (metal organic decomposition) process, an MOCVD (metal organic chemical vapor deposition) process, a sputtering process or a coating process on the capacitive lower electrodes 211 and the first insulating film 212. Then, a platinum film is deposited by a sputtering process to a thickness of 50 nm to 100 nm on the ferroelectric film. Thereafter, the platinum film and the ferroelectric film are patterned, thereby forming capacitive upper electrodes 214 and a capacitive insulating film 213 out of the platinum film and the ferroelectric film, respectively. In this manner, capacitors constituted by the capacitive lower electrodes 211, the capacitive insulating film 213 and the capacitive upper electrodes 214 are formed.

Then, as shown in FIG. 8A, a second insulating film 215 which is made of an undoped silicon oxide film with a thickness of 50 nm to 200 nm and is to be a diffusion barrier film is formed over the first insulating film 212 to cover the capacitive insulating film 213 and the capacitive upper electrodes 214. In this case, the second insulating film 215 is deposited under conditions of O₃ concentration: 11 wt %, flow rate of O₃ gas: 5500 mL/min. (under standard conditions), flow rate of He₂ gas: 4000 mL/min. (under standard conditions), flow rate of N₂ gas: 2000 mL/min. (under standard conditions), flow rate of TEOS (Si(OC₂H₅)₄) gas: 350 mg/min., temperature: 400° C., pressure: 6650 Pa and time: 10 seconds, for example.

Then, a third insulating film 216 of a BPSG film is deposited by, for example, an ozone CVD process to a thickness of 300 nm to 700 nm on the second insulating film 215. This BPSG has a boron concentration of 0.5 wt % to 6.0 wt % and a phosphorus concentration of 1.0 wt % to 6.0 wt %. The BPSG film is deposited under conditions of O₃ concentration: 11 wt %, flow rate of O₃ gas: 4000 mL/min. (under standard conditions), flow rate of He₂ gas: 4000 mL/min. (under standard conditions), flow rate of N₂ gas: 2000 mL/min. (under standard conditions), flow rate of TEOS gas: 500 mg/min., flow rate of TMPO(PO(OCH₃)₃) gas: 23 mg/min., flow rate of TEB(B(OC₂H₅)₃) gas: 100 mg/min., temperature: 480° C., pressure: 26600 Pa and time: 50 seconds, for example. As the third insulating film 216, an undoped silicon oxide film or a silicon oxide film doped with boron or phosphorus may be used instead of the BPSG film, by adding one of or none of the TMPO(PO(OCH₃)₃) gas and the TEB(B(OC₂H₅)₃) gas to the process gas.

Then, selective dry etching is performed on the third insulating film 216, the second insulating film 215, the first insulating film 212 and the first hydrogen barrier film 208, thereby forming the third insulating film 216, the second insulating film 215, the first insulating film 212 and the first hydrogen barrier film 208 into an island shape. In this case, the selective dry etching is performed such that the edges of the capacitive upper electrodes 214 are not exposed from the third insulating film 216 and the second insulating film 215.

Thereafter, as shown in FIG. 8B, oxygen annealing is performed using RTA at 650° C. to 850° C. in an oxygen atmosphere for 15 seconds to 30 minutes, thereby crystallizing the ferroelectric film constituting the capacitive insulating film 213 and causing reflowing of the third insulating film 216. This reflowing process makes portions of the third insulating film 216 corresponding to the edges of the ferroelectric capacitors rounded. In this case, since the second insulating film 215 of the undoped silicon oxide film is interposed between the third insulating film 216 of the BPSG film and each of the capacitive upper electrodes 214 and the capacitive insulating film 213, it is possible to prevent boron or phosphorus constituting the third insulating film 216 from diffusing into the capacitive upper electrodes 214 and the capacitive insulating film 213.

Subsequently, as shown in FIG. 8C, a second hydrogen barrier film 217 of an Al₂O₃ film or a TiAlO film is deposited by sputtering to a thickness of 5 nm to 100 nm to completely cover the third insulating film 216, the second insulating film 215, the first insulating film 212 and the first hydrogen barrier film 208 which have been etched into an island shape. Then, the second hydrogen barrier film 217 is patterned and removed in part except for a portion surrounding the island-shaped third insulating film 216, second insulating film 215, first insulating film 212 and first hydrogen barrier film 208. In this case, the connection between the bottom of the second hydrogen barrier film 217 and the periphery of the first hydrogen barrier film 208 is also maintained.

According to the third embodiment, after the portions of the third insulating film 216 corresponding to the edges of the ferroelectric capacitors have been rounded by the reflowing process on the third insulating film 216, the second hydrogen barrier film 217 is deposited. Accordingly, though the second hydrogen barrier film 217 is deposited by sputtering, the coverage in the portions of the second hydrogen barrier film 217 corresponding to the edges of the ferroelectric capacitors is enhanced. This improves the crystallinity and density of the second hydrogen barrier film 217 in every part so that the occurrence of a hydrogen path is prevented. As a result, the barrier function of the second hydrogen barrier film 217 against hydrogen improves.

The reflowing of the third insulating film 216 and the crystallization of the ferroelectric film constituting the capacitive insulating film 213 are performed with the same oxygen annealing. Accordingly, increase of the number of process steps is suppressed.

As described above, according to the first and second semiconductor devices and the first and second methods for fabricating the semiconductor device, the capacitive lower electrodes are provided on the first hydrogen barrier film and the second hydrogen barrier film is formed on the second insulating film having sloped portions corresponding to the edges of the capacitive upper electrodes, thus ensuring the prevention of the entry of hydrogen into the capacitive insulating film.

What is claimed is:

1. A semiconductor device comprising:
a first hydrogen barrier film formed over a substrate;
a capacitive lower electrode formed on the first hydrogen barrier film;
a first insulating film formed on the first hydrogen barrier film to cover a side of the capacitive lower electrode and have the upper surface of the capacitive lower electrode exposed therefrom;
a capacitive insulating film made of an insulating metal oxide and formed across the boundary between the capacitive lower electrode and the first insulating film;
a capacitive upper electrode formed on the capacitive insulating film;
a second insulating film formed on the first insulating film to cover the capacitive insulating film and the capacitive upper electrode and having a sloped portion at a position corresponding to an edge of the capacitive upper electrode; and
a second hydrogen barrier film formed on the second insulating film.

2. A semiconductor device comprising:
a first hydrogen barrier film formed over a substrate;
a capacitive lower electrode formed on the first hydrogen barrier film;
a first insulating film formed on the first hydrogen barrier film to cover a side of the capacitive lower electrode and have the upper surface of the capacitive lower electrode exposed therefrom;
a capacitive insulating film made of an insulating metal oxide and formed across the boundary between the capacitive lower electrode and the first insulating film;
a capacitive upper electrode formed on the capacitive insulating film;
a second insulating film formed on the first insulating film to cover the capacitive insulating film and the capacitive upper electrode;
a third insulating film made of a different material from that of the second insulating film, formed to cover the second insulating film, and rounded by reflowing in a portion corresponding to an edge of the capacitive upper electrode; and
a second hydrogen barrier film formed on the third insulating film.

3. The semiconductor device of claim 1 or 2, wherein a ferroelectric capacitor constituted by the capacitive lower electrode, the capacitive insulating film and the capacitive upper electrode is completely covered with the first and second hydrogen barrier films.

4. The semiconductor device of claim 3, wherein the first and second insulating films are formed into an island shape and the periphery of the first hydrogen barrier film is connected to the bottom of the second hydrogen barrier film so that the ferroelectric capacitor is completely covered with the first and second hydrogen barrier films.

5. The semiconductor device of claim 1 or 2, wherein the capacitive lower electrode is made of a multilayer film in which a TiN film, a TiAlN film, an Ir film, an IrO₂ film and a Pt film are stacked in this order.

6. The semiconductor device of claim 2, wherein the third insulating film is formed with an ozone CVD process and made of an undoped silicon oxide film or a silicon oxide film doped with at least one of boron or phosphorus.

7. A method for fabricating a semiconductor device, the method comprising the steps of:
forming a first hydrogen barrier film over a substrate with a protective insulating film interposed therebetween;
forming a capacitive lower electrode on the first hydrogen barrier film;
forming a first insulating film on the first hydrogen barrier film so that the first insulating film covers a side of the capacitive lower electrode and the upper surface of the capacitive lower electrode is exposed;
forming a capacitive insulating film of an insulating metal oxide so that the capacitive insulating film covers the boundary between the capacitive lower electrode and the first insulating film;
forming a capacitive upper electrode on the capacitive insulating film;
forming a second insulating film on the first insulating film so that the second insulating film covers the capacitive insulating film and the capacitive upper electrode;
forming a sloped portion in the second insulating film at a position corresponding to an edge of the capacitive upper electrode; and
forming a second hydrogen barrier film on the second insulating film having the sloped portion.

8. The method of claim 7, wherein the step of forming the sloped portion comprises the step of performing sputtering on the second insulating film with inert ions to form the sloped portion.

9. The method of claim 7, wherein the step of forming the sloped portion comprises the step of etching the entire surface of the second insulating film to form the sloped portion.

10. The method of any one of claims 7 to 9, further comprising the step of selectively etching the second insulating film and the first insulating film to form the second insulating film and the first insulating film into an island shape, between the step of forming the sloped portion and the step of forming the second hydrogen barrier film,
wherein the step of forming the second hydrogen barrier film comprises the step of connecting the periphery of the first hydrogen barrier film and the bottom of the second hydrogen barrier film to each other so that a ferroelectric capacitor constituted by the capacitive lower electrode, the capacitive insulating film and the capacitive upper electrode is completely covered with the first and second hydrogen barrier films.

11. A method for fabricating a semiconductor device, the method comprising the steps of:
forming a first hydrogen barrier film over a substrate with a protective insulating film interposed therebetween;
forming a capacitive lower electrode on the first hydrogen barrier film;
forming a first insulating film on the first hydrogen barrier film so that the first insulating film covers a side of the capacitive lower electrode and the upper surface of the capacitive lower electrode is exposed;
forming a capacitive insulating film of an insulating metal oxide so that the capacitive insulating film covers the boundary between the capacitive lower electrode and the first insulating film;
forming a capacitive upper electrode on the capacitive insulating film;
forming a second insulating film on the first insulating film so that the second insulating film covers the capacitive insulating film and the capacitive upper electrode;
forming, on the second insulating film, a third insulating film made of a different material from that of the second insulating film;
performing a reflowing process on the third insulating film so that a portion of the third insulating film corresponding to an edge of the capacitive upper electrode is rounded; and
forming a second hydrogen barrier film on the third insulating film having the rounded portion corresponding to the edge of the capacitive upper electrode.

12. The method of claim 11, wherein the step of forming the third insulating film comprises the step of performing an ozone CVD process to form the third insulating film made of an undoped silicon oxide film or a silicon oxide film doped with at least one of boron and phosphorus.

13. The method of claim 11 or 12, further comprising the step of selectively etching the third insulating film, the second insulating film and the first insulating film to form the third insulating film, the second insulating film and the first insulating film into an island shape, between the step of performing the reflowing process on the third insulating film and the step of forming the second hydrogen barrier film,
wherein the step of forming the second hydrogen barrier film comprises the step of connecting the periphery of the first hydrogen barrier film and the bottom of the second hydrogen barrier film to each other so that a ferroelectric capacitor constituted by the capacitive lower electrode, the capacitive insulating film and the capacitive upper electrode is completely covered with the first and second hydrogen barrier films.

14. The method of claim 7 or 11, wherein the capacitive lower electrode is made of a multilayer film in which a TiN, a TiAlN film, an Ir film, an IrO₂ film and a Pt film are stacked in this order.
